(19) United States
(12) Patent Application Publication
(10) Pub. No.: US 2016/0336047 A1
(43) Pub. Date: Nov. 17, 2016

(54) SIGNAL RETURN PATH

(71) Applicant: HEWLETT PACKARD ENTERPRISE DEVELOPMENT LP, Houston, TX (US)

(72) Inventors: Melvin K BENEDICT, Magnolia, TX (US); Karl J BOIS, Fort Collins, CO (US); Stephen F CONTRERAS, Spring, TX (US); Mark FRANK, Plymouth, OR (US)

(21) Appl. No.: 15/112,995

(22) PCT Filed: Jan. 31, 2014
(86) PCT No.: PCT/US2014/014012

§ 371 Date: Jul. 20, 2016

(51) Int. Cl. G11C 5/06; H01L 23/498; H01L 23/50

(52) U.S. Cl. CPC G11C 5/063; H01L 23/50; H01L 23/49838

(57) ABSTRACT

A system can include a memory circuit having a first signal via, a first signal return via, and at least one second signal return via located closer to the control signal via than the first signal return via.

### BACKGROUND

In the electronics industry, there are many different signal interconnection specifications and designs. Electronic industry standards function to advance electronic technologies by facilitating interconnection and interoperability between different electrical components. Interconnection standardization can attempt to create uniform circuit arrangements for interoperability between apparatus of different manufacture, including control signal and signal return path configurations. However, an interconnection standardized to facilitate interoperability can involve compromise(s) between various competing considerations. As such, compliance to an electronic industry standard can constrain certain electrical component design and performance.

### BRIEF DESCRIPTION OF THE DRAWINGS

FIG. 1 is a top view diagram illustrating vias and capacitive coupling therebetween in an example interconnection configuration having standard and non-standard signal return paths in accordance with implementations described herein.

FIG. 2 is a side view diagram illustrating an example interconnection apparatus configuration having a plurality of non-standard signal return paths in accordance with implementations described herein.

FIG. 3 is a top view circuit layout diagram illustrating an example interconnection configuration including non-standard signal return paths in accordance with implementations described herein.

### DETAILED DESCRIPTION

As computing capabilities improve by increasing communication signal speeds, decreasing apparatus size and spacing, and decreasing power usage, the effects of noise presents an ever increasing challenge. Decreased apparatus size can involve decreased component size and spacing, which can increase capacitive coupling between components and signal paths as the distance therebetween decreases. Speed increases are often implemented via increases in communication frequency. Faster switching between signal data states can generate associated higher frequency noise. Capacitors, including capacitively coupled components, pass higher frequency signals more easily than lower frequency signals. As such, higher frequency noise is passed more easily from one component to another over shorter distances through the increased capacitive coupling.

Efforts to decrease power usage and improve transition time between voltage levels corresponding to different signal data states can involve using reduced voltage levels. As a signal data state signal voltage level decreases, a given noise magnitude becomes a higher percentage of the reduced voltage level of the signal data state. As such, decreasing signal data state signal voltage levels increases susceptibility to the noise influence. As a result, while more higher frequency noise is being generated and higher frequency noise is being transmitted more readily by capacitively coupled components, the tolerance for noise in circuits is less. Signal integrity is challenged by increased noise generation and decreased tolerance for noise. Interconnection standards aimed at facilitating interoperability between apparatus such as memory can constrain apparatus configuration to address such greater signal integrity challenges.

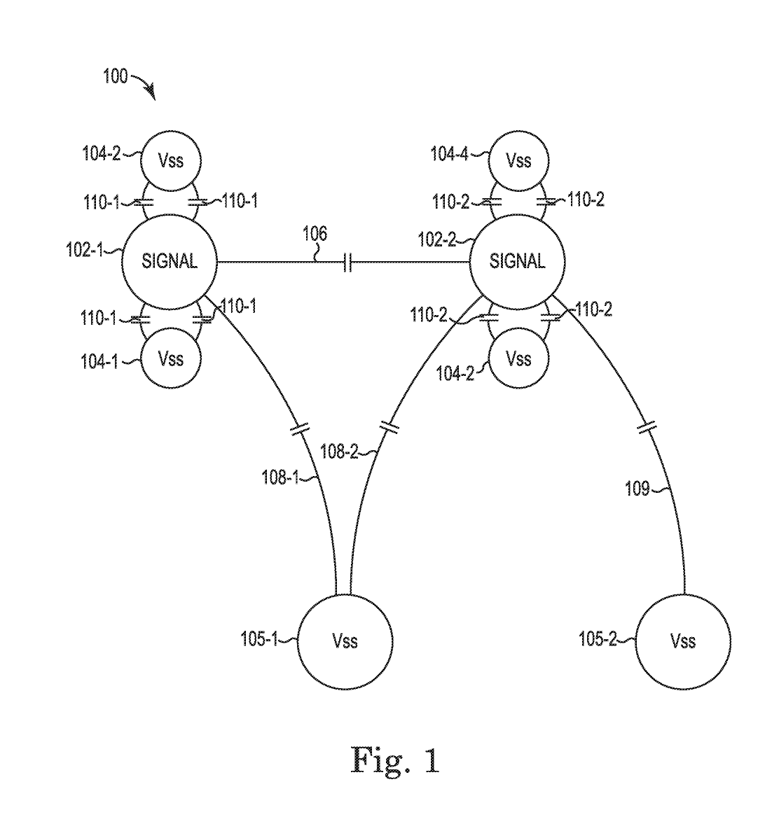

FIG. 1 is a top view diagram illustrating vias and capacitive coupling therebetween in an example interconnection configuration having standard and non-standard signal return paths in accordance with implementations described herein. As used herein, “non-standard” refers to an apparatus characteristic/feature that is not specified by a designated industry interoperability specification, e.g. interoperability specification accepted and/or endorsed by an industry such as the electronics industry. As such, a non-standard via can be a characteristic/feature that does not comply with the designated industry specification for interconnection interoperability, or can be a characteristic/feature that is not addressed in the designated industry specification for interconnection interoperability, such as an additional via other than those set forth in the designated industry specification for interconnection interoperability.

An additional characteristic/feature might not affect interoperability according to the designated industry specification for interconnection interoperability. That is, an apparatus may comply with the designated industry specification for interconnection interoperability by having specified characteristic(s)/feature(s) to achieve interoperability and have an additional characteristic/feature that does not diminish compliance of the apparatus with the designated industry specification for interconnection interoperability while providing an additional benefit to the apparatus.

The interconnection apparatus shown in FIG. 1 includes signal line and return path configuration fixed by compliance with an interconnection standard. The features shown in FIG. 1 include vias for signal paths and return signal paths. As used herein, the vias can include circuitry, silicon, and/or plated-through holes (PTHs), in a portion of a given interconnection configuration. A PTH is a particular type of via that can be used for making interconnections between levels in order to make contact with conductive materials at various levels. The vias can be associated with various signal paths, as illustrated. Configuration, including location, of some of the features are fixed by compliance with an interconnection standard.

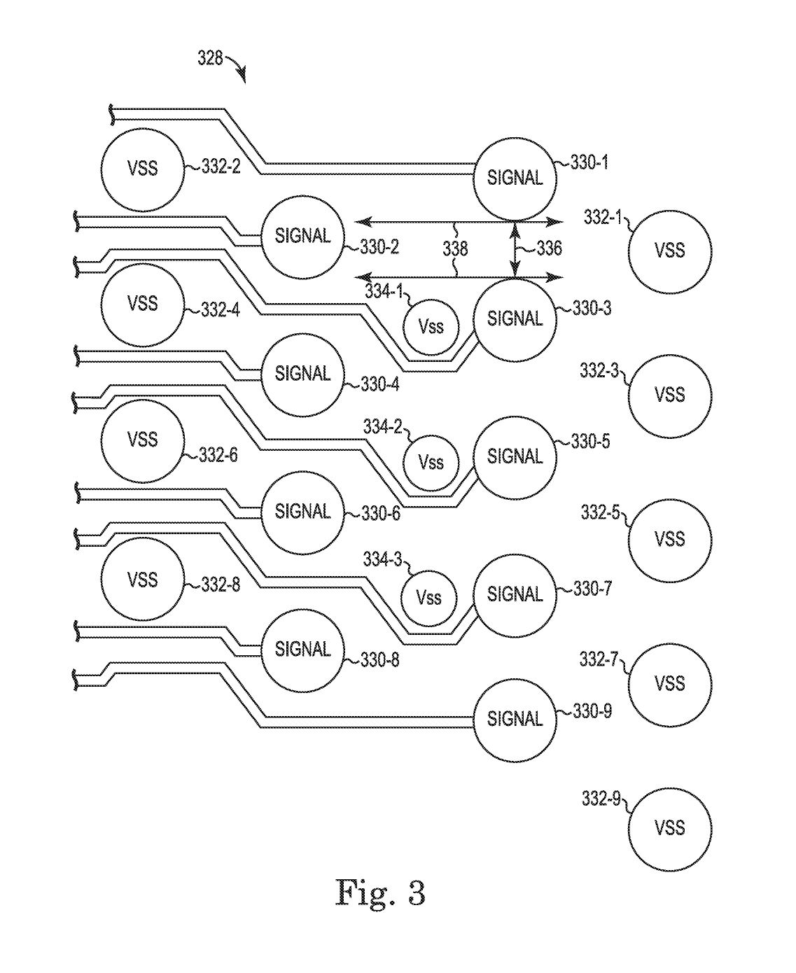

FIG. 1 shows a PTH for a first signal path 102-1 and a PTH for a first signal return path 105-1 (associated with the first signal path 102-1). The PTHs shown in FIG. 1 can be through a particular level, such as through a level having a circuit thereon (as is shown in FIG. 3). The PTHs can be located, for example, to provide an interconnection between a socket and a memory system “motherboard.” Sockets can be mounted using through hole or surface mount (SMT) techniques. Memory, e.g., a dual in-line memory module (DIMM), can be physically coupled into the socket. The vias, e.g., PTHs, can provide interconnection from the socket to one or more levels comprising the memory system “motherboard,” for instance. However, embodiments of the present disclosure are not limited to memory system “motherboard”/DIMM socket interconnections and the techniques and configurations provided in the present disclosure can be implemented in other interconnections involving signal paths and return signal paths.

The relative locations of the PTH for the first signal path 102-1 and the PTH for the first signal return path 105-1 are fixed in compliance with a particular interconnection standard. FIG. 1 also shows a PTH for a second signal path 102-2 and a PTH for a first signal return path 105-2 (associated with the second signal path 102-2), which are also located in compliance with the particular interconnection standard, both in terms of the relative locations to one another and also in terms of their locations with respect to the PTH for the first signal path 102-1 and the PTH for the first signal return path 105-1. The PTHs for the signal paths and signal return paths can, for example, include PTHs for conducting different signals, e.g., address bus, data bus, clock signal, etc.

FIG. 1 indicates some of the communicative coupling, e.g., capacitive coupling, between the various PTHs. Communicative coupling provides a path for noise transmission. Capacitive coupling between PTHs provides an unintended path for noise transmission. In electronics, capacitive coupling can transfer energy within an electrical network by means of the capacitance between circuit nodes. Capacitive coupling can be unintended. Capacitance exists between two conductors that are in proximity to one another. When there is a voltage, e.g., potential difference, between the two conductors, an electric field exists therebetween, and energy can be transmitted between the conductors by the electric field.

Often one signal can capacitively couple with another and cause what appears to be noise. Higher frequency energy is passed through a capacitor more easily than lower frequency energy. Therefore, as electrical circuit signal frequency increases, more noise passes through portions of the electrical circuit that are capacitively-coupled. To reduce capacitive coupling, wires or traces are often separated as much as possible, or ground lines or ground planes are run in between signals that might affect each other.

FIG. 1 illustrates a capacitance 106 due to capacitive-coupling between the first signal path 102-1 and the second signal path 102-2, and a capacitance 108-1 due to capacitive-coupling between first signal path 102-1 and the first signal return path 105-1. FIG. 1 also shows a capacitance 108-2 due to capacitive-coupling between the second signal path 102-2 and the first signal return path 105-1, e.g., the signal return path associated with the first signal path 102-1, as well as a capacitance 109 due to capacitive-coupling between the second signal path 102-2 and the first signal return path 105-2, e.g., a signal return path associated with the second signal path 102-2.

FIG. 1 shows the strongest capacitive coupling influences. Of course, capacitively-coupling exists between all respective PTHs, e.g., the first signal path 102-1 and the first signal return path 105-2 (associated with the second signal path 102-2), etc. but due to greater distances the capacitive coupling may be diminished. For these reasons such noise paths are not shown in FIG. 1.

The first signal return paths 105-1, 105-2, are shown on FIG. 1 as being at Vss potential, which indicates a power supply negative terminal voltage. A power supply provides a voltage difference at a positive terminal with respect to a negative terminal. The negative terminal is often used as a reference point in the electrical circuit(s) to which the power supply is coupled. The power supply negative terminal may be coupled to an external ground reference potential, e.g., earth ground, or referred to as ground for being a common potential reference point in the electrical circuit(s). Shorthand notation can be used in electrical drawings, and when describing electrical circuits, to indicate the voltage associated with various locations in the electrical circuit including power supply positive and negative terminals. In electrical circuits the shorthand notation Vdd is often used to indicate a power supply positive terminal and Vss is often used to indicate a power supply negative terminal, which may also be the ground reference potential.

Vss, as shown in FIG. 1, can be a reference potential, and referred to a circuit “ground” or signal “ground” whether or not the power supply negative terminal is connected to an external ground. However, embodiments of the present disclosure are not limited to the signal return path being Vss, and the signal return path can be associated with other potentials and circuit nomenclatures. The first signal return paths 105-1, 105-2, shown on FIG. 1 can, for example, connect between ground planes that are located perpendicular to each side of the level through which the PTHs are shown in top view passing therethrough.

According to various embodiments of the present disclosure, FIG. 1 also shows a number of additional signal return vias associated with each signal PTH. More particularly, FIG. 1 shows two additional signal return vias associated with each signal PTH. However, embodiments are not limited to this quantity of additional signal return vias, and may include more or fewer signal return vias in addition to the PTH for the signal return path dictated by the interconnection standard, e.g., the PTH for the first signal return path 105-1 (associated with the PTH for the first signal path 102-1) and the PTH for the first signal return path 105-2 (associated with the PTH for the second signal path 102-2), etc. That is, embodiments of the present disclosure for an interconnection configuration includes at least one signal return via associated with a PTH for a signal path in addition to the PTH for the first signal return associated with each respective PTH for a signal path, the signal paths and first signal return paths having locations dictated by an interconnection standard.

FIG. 1 shows two second signal return paths in proximity to the PTH for each signal path. Specifically, FIG. 1 shows PTHs for second signal return paths 104-1 and 104-2 in closer proximity to the first signal path 102-1, and PTHs for second signal return paths 104-3 and 104-4 in close proximity to the second signal path 102-2. Capacitive coupling between the respective signal paths and the PTHs for signal return paths in proximity to the PTH for each signal path are shown on FIG. 1. Capacitive coupling is shown between the PTH for the first signal path 102-1 and the PTH for the second signal return path 104-1 by capacitance 110-1. Capacitive coupling is shown between the PTH for the first signal path 102-1 and the PTH for the second signal return path 104-2 by capacitance 110-1. Capacitive coupling is shown between the PTH for the second signal path 102-2 and the PTH for the second signal return path 104-3 by capacitance 110-2. Capacitive coupling is shown between the PTH for the second signal path 102-2 and the PTH for the second signal return path 104-4 by capacitance 110-2.

The additional signal return paths in closer proximity to the first signal path, e.g., second signal return path vias, act as electric field “getters.” A “getter” is a term that originally was used in the manufacture of vacuum tubes with respect to improving vacuum within a tube. However, referring to the additional closer signal return path(s) as “getters” reflects that the nearer signal return path via(s) absorb a majority of undesirable noise energy in a manner analogous to the way in which a reactive material placed inside a vacuum tube absorbed gas molecules. Presence of the additional closer signal return path(s) vias to the signal via leaves less noise energy in the electric field between adjacent signal vias, thereby reducing noise transmission therebetween. That is, the capacitive coupling between PTHs, e.g., first signal path 102-1 and second signal path 102-2, for standardized features as defined by a particular interconnection standard can be greater where additional (and closer) signal return path(s) are not implemented.

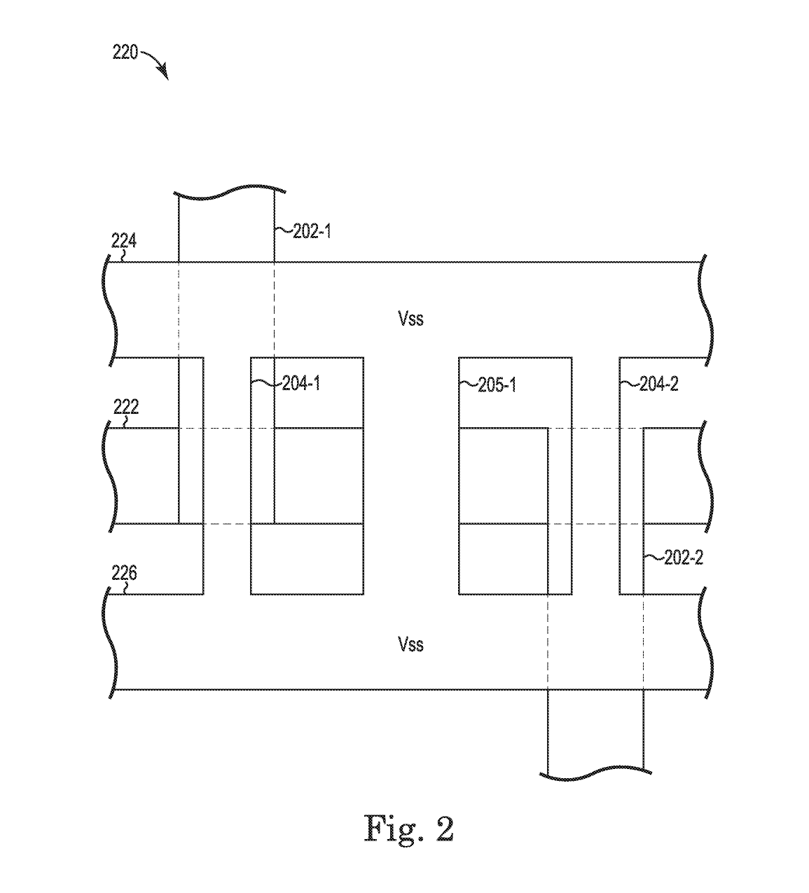

Also, presence of the additional closer signal return path via(s) does not interfere with interoperability of the interconnection in accordance with a designated industry specification for interconnection interoperability since the configuration shown in FIG. 1 also includes signal vias and signal return vias in compliance with the designated industry specification for interconnection interoperability (as discussed further with respect to FIG. 2). While moving an associated signal return path via closer to a signal via might likewise increase capacitive coupling between the signal via and associated signal return path via and thereby sink noise energy that otherwise could pass from one signal path via to another, e.g., cross-talk, by capacitive coupling therebetween, such reconfiguration of locations of signal path vias and/or signal return path vias would not comply with the designated industry specification for interconnection interoperability (which fix location of signal path vias and/or signal return path vias for interoperability). As such, addition of one or more signal return path(s) vias located closer to the associated signal path via than the standard signal return path via does not affect compliance of the interconnection with the designated industry specification for interconnection interoperability.

The capacitive coupling between the PTH for a respective signal path and the PTH for the second signal return path(s) in close proximity thereto are stronger than the capacitive coupling between the PTH for a respective signal path and the PTH for the first signal return path due to the shorter distances, i.e., the PTH(s) for the second signal return path is located in closer proximity to the PTH for the signal path than the PTH for the first signal return path. As such, the stronger capacitive coupling is indicated on FIG. 1 by a relatively greater quantity of capacitors, e.g., 2, for the capacitive coupling between the PTH for a respective signal path and the PTH for the second signal return path(s) than the quantity of capacitors, e.g., 1, for the capacitive coupling between the PTH for a respective signal path and the PTH for the first signal return path (and also between PTHs for different signal paths).

Embodiments of the present disclosure are not limited to the size and/or relative locations and/or shape and/or other characteristics of the second signal return path(s) shown in FIG. 1 and can be implemented using second signal return path(s) of different size and/or location and/or orientation to other PTH feature than is shown in FIG. 1. For example, a PTH for a second signal return path can be located between PTHs for signal paths, or more directly between a PTH for a signal path and a PTH for an associated (or other) first signal return path or PTH for other than a signal return path.

According to various embodiments, the PTHs for the second signal return paths has a same potential as the first signal return paths, e.g., Vss voltage, as indicated in FIG. 1. That is, the PTHs for the second signal return paths can also be connected to ground plane(s) located on either side (or both sides) of the level through which the PTHs are shown passing in the top view of FIG. 1.

According to various embodiments of the present disclosure, the PTH for the at least one second signal return is located within 5 mils of the PTH for the first signal path, particularly where the PTH for the first signal return is not located within 5 mils of the PTH for the first signal path. According to various embodiments, the PTH for the at least one second signal return has a diameter of at most 9 mils. However, embodiments of the present disclosure are not limited to these dimensions, and some embodiments may include a PTH for the at least one second signal return that have a diameter that is larger or smaller than 9 mils. For example, the PTH for the at least one second signal return may be formed by the smallest via which can be formed using technology used to form components having a particular pitch.

The JEDEC Solid State Technology Association (referred to herein as “JEDEC”), formerly known as the Joint Electron Device Engineering Council, is an independent semiconductor engineering trade organization and standardization body. JEDEC was founded in 1958 as a joint activity between EIA and the National Electrical Manufacturers Association (NEMA) to develop standards for semiconductor devices. JEDEC adopts open industry specifications, e.g., standards, which permit any and all interested companies to freely manufacture in compliance with adopted standards. The JEDEC standards serve to advance electronic technologies by, for example, facilitating interoperability between different electrical components.

Memory used in computing can include random access memory (RAM) such as dynamic random access memory (DRAM) and synchronous dynamic random access memory (SDRAM). Single data rate (SDR) SDRAM can accept one command and transfer one word of data per clock cycle. A double data rate (DDR) interface uses the same commands, accepted once per cycle, but reads or writes two words of data per clock cycle, which is accomplished by reading and writing data on both the rising and falling edges of the clock signal. As such, DDR SDRAM (sometimes referred to as DDR1 technology) doubles the minimum read or write unit because every access refers to at least two data words.

DDR2, DDR3, and DDR4 SDRAM are second, third, and fourth generation DDR SDRAM technologies set forth in respective JEDEC standards. Newer DDR versions provided various means for faster operation and often with lower power consumption achieved by use of higher frequency signals, improved use of data strobes, lower operating voltages, decreased spacing, i.e., pitch, and changed component topologies.

JEDEC released the final specification of DDR4 in September 2012. DDR4 SDRAM memory utilizes a 1.2 V operating voltage (versus 1.5 V for DDR3 memory) and achieves increased data speeds in the range of 1.6 to 3.2 billion transfers per second (1600-3200 Mbps). DDR4 also specifies a smaller pitch and via hole diameter than DDR3. The combination of higher frequency and smaller pitch/dimensions can increase capacitive coupling, and thus noise transmission. Also, generated noise can be more disruptive to DDR4 control signals since the operating voltage is decreased from DDR3. A noise signal of a given magnitude is greater relative to a DDR4 control signal maximum voltage level than it is to a DDR3 control signal maximum voltage level. As such, DDR4 signal integrity is challenged by increased noise generation and decreased tolerance for noise.

A single in-line memory modules (SIMM) and dual in-line memory modules (DIMM) comprise a number of DRAMs. These memory modules can be mounted, e.g., on a memory system board such as a printed circuit board (PCB), and used in computing devices. The memory modules can plug into sockets mounted on a memory system board, for instance. DIMMs have separate electrical contacts on each side of the module.

A PCB can mechanically support and electrically connect electronic components using conductive tracks, pads and other features etched from conductive materials, e.g., copper sheets, laminated or deposited onto a non-conductive substrate. PCB's can be single-sided, e.g., one conductive level, double-sided, e.g., two conductive levels, or multi-level with more than two levels. Conductive materials on different levels can be connected with vias, e.g., plated-through holes (PTHs). One example memory configuration includes a number of sockets mounted on a memory system board, e.g., PCB. A DIMM can be mounted in each socket, which mechanically and electrically couples the DIMM to the memory system board.

According to various embodiments of the present disclosure, the PTHs for the signal paths and first signal return paths, can have a configuration specified by a JEDEC standard, such as DDR3 and/or DDR4, for an interconnection. The interconnection may be, for example, an interconnection between memory, such as between DIMM modules and a system board to which the DIMM modules are mounted. However, embodiments of the present disclosure are not limited to interconnections, or interconnections specified by JEDEC, or interconnections specified by DDR3 and/or DDR4 standards. Second signal return paths in closer proximity than first signal return paths that are fixed according to constraints of a standard configuration in compliance with interoperability specifications can be implemented according to the present disclosure in many other applications and topologies.

FIG. 2 is a side view diagram illustrating an example interconnection apparatus 220 configuration having a plurality of non-standard signal return paths in accordance with implementations described herein. FIG. 2 can correspond to a portion of the configuration shown in top view in FIG. 1. FIG. 2 shows a level 222, e.g., board, through which various PTHs pass. FIG. 2 also shows that ground planes, e.g., 224 and 226, may be located on either side, e.g., both sides, of the board 222. The PTH for a first signal return 205-1 can connect to one or more of, e.g., between, ground planes 224 and 226, as shown. The PTHs for second signal return paths 204-1 and 204-2 can also connect to one or more of, e.g., between, ground planes 224 and 226, as shown. The PTHs for the signal paths, e.g., first signal path 202-1 and second signal path 202-2, can extend in either direction (or both directions) from board 222. FIG. 2 shows first signal path 202-1 extending up from board 222 and shows second signal path 202-2 extending down from board 222, for instance.

However, embodiments of an interconnection configuration according to the present disclosure are not limited to that shown in FIG. 2, including the quantity, size, and/or location(s) of the PTHs for the second signal return paths relative to each other, PTHs for the first return path, and/or PTHs for the signal path(s). Note that a first return path associated with second signal path, e.g., corresponding to first return path 105-2 shown in FIG. 1, is not shown in FIG. 2. Also, FIG. 2 does not show the dielectric material(s) that may be located between board 222 and the ground planes 224 and 226, through which the various PTHs may also pass.

FIG. 3 is a top view circuit layout diagram illustrating an example interconnection configuration including non-standard signal return paths in accordance with implementations described herein. FIG. 3 shows a board 328, such as a memory system board, having PTHs for signal paths and first signal return paths arranged according to an interconnection standard, e.g., JEDEC DDR4. FIG. 3 shows a number of PTHs for signal paths, 330-1 through 330-9, and a number of PTHs for signal return paths 332-1 through 332-9. Each PTH for a signal path has an associated PTH for a signal return path. For instance, the PTH for signal return path 332-1 is associated with the PTH for the signal path 330-1, the PTH for signal return path 332-2 is associated with the PTH for the signal path 330-2, . . . , and the PTH for signal return path 332-9 is associated with the PTH for the signal path 330-9,

The number of PTHs for signal paths, 330-1 through 330-9 are shown having electrical connections, e.g., traces, connected thereto, which can connect the respective PTH to other components on the memory system board 328, for example. The signal paths may be, for example, a portion of a communication bus.

According to various embodiments of the present disclosure, some, but not all of the PTHs for signal paths, 330-1 through 330-9 have PTHs for second signal return paths, e.g., 334-1 through 334-3, located in closer proximity thereto than the respective associated PTHs for first signal return paths, e.g., 332-3, 332-5, 332-7. For example, PTHs for signal paths that are coupled to relatively more other PTHs, can have associated PTHs for second signal return paths, e.g., 334-1 through 334-3, and those PTHs for signal paths that are coupled to relatively fewer other PTHs may not have associated PTHs for second signal return paths.

For example, PTHs for signal paths that are interior to other PTHs for signal paths in the interconnection configuration can have associated PTHs for second signal return paths, and those PTHs for signal paths that are not interior to other PTHs for signal paths in the interconnection configuration may not have associated PTHs for second signal return paths, as shown in FIG. 3. Inclusion of additional signal return paths can be balanced with additional cost to fabricate the additional features, as well as other engineering considerations such as impedance of the interconnection, e.g., transmission line. Additional signal return path(s) can change impedance of the interconnection and cause signal effects associated with unmatched impedances of transmission lines and/or antennas such as signal reflection, etc. According to various embodiments, second signal return path(s) can be added where effect of the additional signal return path(s) do not vary impedance beyond acceptable limits, e.g., 40 ohms, DDR4-specified values, etc., and/or based on signal strength considerations, e.g., dB coupling measures.

Interior refers to a particular PTH for a signal path having a PTH for a different signal path located on each of two sides of the particular PTH for the signal path. However, embodiments of the present disclosure are not so limited and PTHs for signal paths that are not interior to other PTHs for signal paths in the interconnection configuration may have associated PTHs for second signal return paths, and/or, PTHs for signal paths that are interior to other PTHs for signal paths in the interconnection configuration may not have associated PTHs for second signal return paths. The need to have a PTHs for second signal return path associated with a particular PTH for a signal path can be determined based on a signal integrity criteria, such as by testing or modeling.

According to various embodiments of the present disclosure, associated PTH(s) for second signal return paths can be located nearer the PTH for the associated signal path than the PTR for the associated first signal return path is located to the PTH for the associated signal path. However, in some embodiments, the PTH(s) for second signal return paths is located in other than an horizontal area between PTHs for adjacent signal paths, such area being illustrated in FIG. 3 at 334-1. The PTH(s) for second signal return paths can be located so as not to constrict the width 336 between PTHs for adjacent signal paths 438 through which current may flow in other levels, e.g., ground planes, through which the various PTHs may pass.

In the detailed description of the present disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be used and the process, electrical, and/or structural changes may be made without departing from the scope of the present disclosure.

The figures included as part of the present disclosure follow a numbering convention in which the first digit or digits correspond to the drawing figure number and the remaining digits identify an element or component in the drawing. Similar elements or components between different figures may be identified by the use of similar digits. Elements shown in the various examples herein can be added, exchanged, and/or eliminated so as to provide a number of additional examples of the present disclosure.

In addition, the proportion and the relative scale of the elements provided in the figures are intended to illustrate the examples of the present disclosure, and should not be taken in a limiting sense.

The specification examples provide a description of the applications and use of the system and method of the present disclosure. Since many examples can be made without departing from the spirit and scope of the system and method of the present disclosure, this specification sets forth some of the many possible example configurations and implementations.

What is claimed:

1. A system, comprising:
a memory circuit level having:
a first control signal via;
a first signal return via corresponding to the first control signal via;
at least one additional signal return via corresponding to the first control signal via,
wherein the first control signal via, a second control signal via, and the first signal return via are arranged in compliance with a JEDEC DDR4 specification
wherein the at least one additional signal return via is located closer to the first control signal via than the first signal return via.

2. The system of claim 1, wherein the at least one additional signal return via is located within 5 mils of the first control signal via.

3. The system of claim 2, wherein the first signal return via is not located within 5 mils of the first control signal via.

4. The system of claim 1, wherein the at least one additional signal return via has a diameter of at most 9 mils.

5. The system of claim 1, wherein the first control signal via, a second control signal via, and the first signal return via are arranged in compliance with a JEDEC DDR4 specification.

6. The system of claim 1, further comprising a plurality of additional signal return vias corresponding to the first control signal via.

7. The system of claim 1, wherein the at least one additional signal return via is located between the first control signal via and the second control signal via.

8. The system of claim 1, wherein the at least one additional signal return via is a negative power supply return at a Vss reference voltage.

9. An apparatus, comprising:
a first ground plane; and
a circuit level having:
a number of control signal vias therethrough;
a number of first signal return vias therethrough; and
a number of second signal return vias therethrough,
wherein locations of the number of control signal vias and the number of first signal return vias are in compliance with interconnection topology of an electronics industry organization specification, and the number of second signal return vias are located closer to at least one of the number of control signal vias than any one of the number of first signal return vias.

10. The apparatus of claim 9, wherein the first and second signal return vias are electrically coupled to the first ground plane.

11. The apparatus of claim 9, wherein the number of second signal return path vias are located in proximity closer to some of the number of control signal vias than any of the number of first return signal vias and are not the number of second signal return path vias are not located in proximity closer to some other of the number of control signal vias than any of the number of first return signal vias.

12. The apparatus of claim 9, wherein locations of the number of control signal vias and the number of first signal return vias are in compliance with a JEDEC DDR specification.

13. A method of forming an interconnection, comprising:
providing a signal via through a circuit level of the interconnection;
providing a first signal return via corresponding to the signal via through the circuit level of the interconnection;
providing at least one second signal return via corresponding to the signal via through the circuit level of the interconnection,
wherein the at least one second signal return via is located closer to the signal via than the first signal return via, and
wherein a topology of the signal via and the first signal return via of the interconnection is per an industry organization standard specification.

14. The method of claim 13, further comprising providing a plurality of second signal return vias through the circuit level of the interconnection that are each located closer to the signal via than any first signal return via.

15. The method of claim 13, wherein the topology of the signal via and the first signal return via of the interconnection is per a JEDEC DDR4 standard specification for interconnection of DIMM memory to a memory system circuit.
